(19) United States
(12) Patent Application Publication
(10) Pub. No.: US 2026/0367189 A1
(43) Pub. Date: Nov. 19, 2026

(54) TEST DEVICE AND TEST METHOD

(71) Applicants: HIOKI E.E. CORPORATION, Nagano (JP); AISIN CORPORATION, Aichi (JP)

(72) Inventors: Tadashi IIJIMA, Nagano (JP); Hideaki KIMURA, Aichi (JP)

(21) Appl. No.: 19/133,885

(22) PCT Filed: Nov. 28, 2023
(86) PCT No.: PCT/JP2023/042518

§ 371 Date: May 29, 2025

(30) Foreign Application Priority Data
Dec. 9, 2022 (JP) 2022-196802

(51) Int. Cl. G01R 31/72; G01R 31/34; G01R 31/62

(52) U.S. Cl. CPC G01R 31/72; G01R 31/346; G01R 31/62

(57) ABSTRACT

The application presents a test device where in a case in which an instruction acceptance unit accepts a predetermined instruction, a voltage generation circuit generates and outputs a voltage in accordance with a value (Et) obtained by correcting a voltage command value (Ee) associated with the predetermined instruction (A1) by a correction coefficient (C), and a correction coefficient calculation unit updates the correction coefficient (C) such that a gap between a voltage measured by a voltage measurement unit and the voltage command value (Ee) decreases, and when measurement of a winding under test is executed, the voltage generation circuit generates and outputs a voltage in accordance with a value obtained by correcting a voltage command value (Em) associated with the measurement by the correction coefficient (C), and an analysis result generation unit generates an analysis result on the basis of the voltage measured by the voltage measurement unit.

### TECHNICAL FIELD

The present invention relates to a test device and a test method and, for example, relates to a test device and a test method for measuring properties of windings of components and products formed by coils, such as rotating machines and transformers of electric motors, power generators, and the like.

### BACKGROUND ART

As a test device for measuring properties of a winding of a rotating machine of an electric motor, a power generator, and the like, an impulse winding test device that on the basis of changes in voltage occurring when an impulse voltage is applied to a winding under test, measures electric properties of the winding has conventionally been known (see Patent Literature 1).

### DOCUMENT LIST

### Patent Literature

Patent Literature 1: Japanese Patent No. 5405518

### SUMMARY OF INVENTION

### Technical Problem

A conventional impulse winding test device represented by Patent Literature 1 generates an impulse voltage by means of a voltage generation circuit provided in the impulse winding test device and applies the impulse voltage to a winding. At this time, there are many cases in which a difference arises between the impulse voltage generated by the voltage generation circuit and a voltage to be actually applied to the winding.

For example, when a user operates the impulse winding test device to set the impulse voltage at 1000 V and when the impulse voltage of 1000 V is output from the voltage generation circuit, there are cases in which the voltage to be applied to a winding under test decreases to 950 V to 980 V, for example, with respect to the set voltage (1000 V), or varies. This phenomenon is considered to result from a voltage drop due to a parasitic capacitance, an output impedance, and a transient response as well as manufacturing variation in properties of the winding itself or properties of a core that the winding has. Moreover, a winding having a core has a magnetic property having hysteresis, and thus, a state of magnetization of the core is changed by the history of voltages or currents applied to the winding. Therefore, in the case of the winding having the core, the state of magnetization of the core is considered to be also a contributory factor of variation in voltage to be applied. Among these factors, the voltage drop can be corrected by measuring a good product and raising the voltage to be applied to the winding under test by a value to be dropped, and variation in magnetization of the core can be reduced by a degaussing pulse which will be described later.

However, it is difficult to reduce variation in voltage to be applied resulting from manufacturing variation. In addition, variation in voltage to be applied to a winding under test per winding despite that a set value of the impulse voltage is stable makes substantial measuring conditions unstable and is therefore not preferable from the viewpoint of quality management of windings to be performed by a user.

The present invention has been made in view of the problems described above, and has an object to reduce variation in voltage to be applied to a winding when testing the winding.

### Solution to Problem

A test device according to a representative embodiment of the present invention is characterized by including a first external terminal to which one terminal of a winding under test is to be connected, a second external terminal to which another terminal of the winding under test is to be connected, an instruction acceptance unit that accepts an instruction, a correction coefficient calculation unit that calculates a correction coefficient, a voltage generation circuit that generates a voltage on a basis of a voltage command value and the correction coefficient and outputs the voltage across the first external terminal and the second external terminal, a voltage measurement unit that performs measurement of a voltage across the first external terminal and the second external terminal, and an analysis result generation unit that executes an analysis related to an electric property of the winding under test on a basis of the voltage measured by the voltage measurement unit and generates an analysis result, in which in a case in which the instruction acceptance unit accepts a predetermined instruction, the voltage generation circuit generates and outputs a voltage in accordance with a value obtained by correcting the voltage command value associated with the predetermined instruction by the correction coefficient, and the correction coefficient calculation unit updates the correction coefficient such that a gap between the voltage measured by the voltage measurement unit and the voltage command value associated with the predetermined instruction decreases, and in a case in which the analysis is executed, the voltage generation circuit generates and outputs a voltage in accordance with a value obtained by correcting the voltage command value associated with the analysis by the correction coefficient, and the analysis result generation unit generates the analysis result on a basis of the voltage measured by the voltage measurement unit.

### Effects of Invention

A test device according to the present invention enables variation in voltage to be applied to a winding when testing the winding to be reduced.

### BRIEF DESCRIPTION OF DRAWINGS

FIG. 1 A diagram showing a configuration of a test device according to an embodiment

FIG. 2 A diagram showing an example of a configuration of a voltage generation circuit

FIG. 3 A timing chart obtained when a degaussing pulse and a measurement pulse are output from the voltage generation circuit

FIG. 4 A flowchart showing a flow of processing performed by the test device in a degaussing mode

FIG. 5 A flowchart showing a flow of processing performed by the test device in a test mode

### DESCRIPTION OF EMBODIMENTS

### 1. Overview of Embodiment

First, an overview of a representative embodiment of the invention disclosed in the present application will be described. Note that in the following description, reference characters in the drawings corresponding to components of the invention are written in brackets, as an example.

[1] A test device (1) according to a representative embodiment of the present invention is characterized by including a first external terminal (T1) to which one terminal of a winding (11) under test is to be connected, a second external terminal (T2) to which another terminal of the winding under test is to be connected, an instruction acceptance unit (3) that accepts an instruction, a correction coefficient calculation unit (5) that calculates a correction coefficient, a voltage generation circuit (2) that generates a voltage on a basis of a voltage command value and the correction coefficient and outputs the voltage across the first external terminal and the second external terminal, a voltage measurement unit (4) that performs measurement of a voltage across the first external terminal and the second external terminal, and an analysis result generation unit (6) that executes an analysis related to an electric property of the winding under test on a basis of the voltage measured by the voltage measurement unit and generates an analysis result, in which in a case in which the instruction acceptance unit accepts a predetermined instruction (A1), the voltage generation circuit generates and outputs a voltage in accordance with a value obtained by correcting the voltage command value associated with the predetermined instruction by the correction coefficient, and the correction coefficient calculation unit calculates the correction coefficient such that a gap between the voltage measured by the voltage measurement unit and the voltage command value associated with the predetermined instruction decreases, and in a case in which the analysis is executed, the voltage generation circuit generates and outputs a voltage in accordance with a value obtained by correcting the voltage command value associated with the analysis by the correction coefficient, and the analysis result generation unit generates the analysis result on a basis of the voltage measured by the voltage measurement unit.

[2] In the test device according to [1] above, in the case in which the instruction acceptance unit accepts the predetermined instruction, the voltage generation circuit may output a pulse having a voltage (Et) in accordance with the value obtained by correcting the voltage command value associated with the predetermined instruction by the correction coefficient a specified number of times of output, and the correction coefficient calculation unit may update the correction coefficient each time the pulse is output.

[3] In the test device according to [1] or [2] above, the correction coefficient calculation unit may update the correction coefficient on a basis of a ratio between the voltage (V) measured by the voltage measurement unit and the voltage command value (Ee) associated with the predetermined instruction.

[4] In the test device according to any one of [1] to [3] above, the predetermined instruction is an instruction (A1) to output a degaussing pulse which is a voltage for reducing variation in magnetization of a core in the winding having the core, and in a case in which the instruction acceptance unit accepts an instruction (A2) to execute the analysis after calculation of the correction coefficient, the voltage generation circuit may generate and output the voltage in accordance with the value obtained by correcting the voltage command value (Em) associated with the analysis by the correction coefficient, and the analysis result generation unit may generate the analysis result on the basis of the voltage measured by the voltage measurement unit.

[5] In the test device according to any one of [1] to [3] above, the predetermined instruction is an instruction (A2) to execute the analysis, and after calculation of the correction coefficient, the voltage generation circuit may generate and output the voltage in accordance with the value obtained by correcting the voltage command value (Em) associated with the analysis by the correction coefficient, and the analysis result generation unit may generate the analysis result on the basis of the voltage measured by the voltage measurement unit.

[6] In the test device according to any one of [1] to [4] above, the voltage command value (Ee) associated with the predetermined instruction may correspond to the voltage command value (Em) associated with the measurement.

[7] A method according to a representative embodiment of the present invention is a test method to be performed using a test device including a first external terminal to which one terminal of a winding under test is to be connected, a second external terminal to which another terminal of the winding under test is to be connected, an instruction acceptance unit that accepts an instruction, a correction coefficient calculation unit that calculates a correction coefficient, a voltage generation circuit that generates a voltage on a basis of a voltage command value having been set and the correction coefficient and outputs the voltage across the first external terminal and the second external terminal, a voltage measurement unit that measures a voltage across the first external terminal and the second external terminal, and an analysis result generation unit that executes an analysis related to an electric property of the winding under test on a basis of the voltage measured by the voltage measurement unit and generates an analysis result. The present method is characterized by including a first step (S1, S2) in which the instruction acceptance unit accepts a predetermined instruction, a second step (S3 to S6) in which, after the first step, the voltage generation circuit generates and outputs a voltage in accordance with a value obtained by correcting the voltage command value associated with the predetermined instruction by the correction coefficient, a third step (S7) in which the voltage measurement unit measures a voltage across the first external terminal and the second external terminal obtained when the voltage generation circuit outputs the voltage in the second step, a fourth step (S8) in which the correction coefficient calculation unit calculates the correction coefficient such that a gap between the voltage measured in the third step and the voltage command value associated with the predetermined instruction decreases, a fifth step (S13 to S16) in which in a case in which the analysis is executed, the voltage generation circuit generates and outputs a voltage in accordance with a value obtained by correcting the voltage command value associated with the analysis by the correction coefficient, a sixth step (S17) in which the voltage measurement unit measures a voltage across the first external terminal and the second external terminal obtained when the voltage generation circuit outputs the voltage in the fifth step, and a seventh step (S19) in which the analysis result generation unit generates the analysis result on a basis of the voltage measured in the sixth step.

### 2. Specific Example of Embodiment

Hereinafter, a specific example of an embodiment of the present invention will be described with reference to the drawings. Note that in the following description, common components in each embodiment will be denoted by the same reference characters, and repeated description will be omitted.

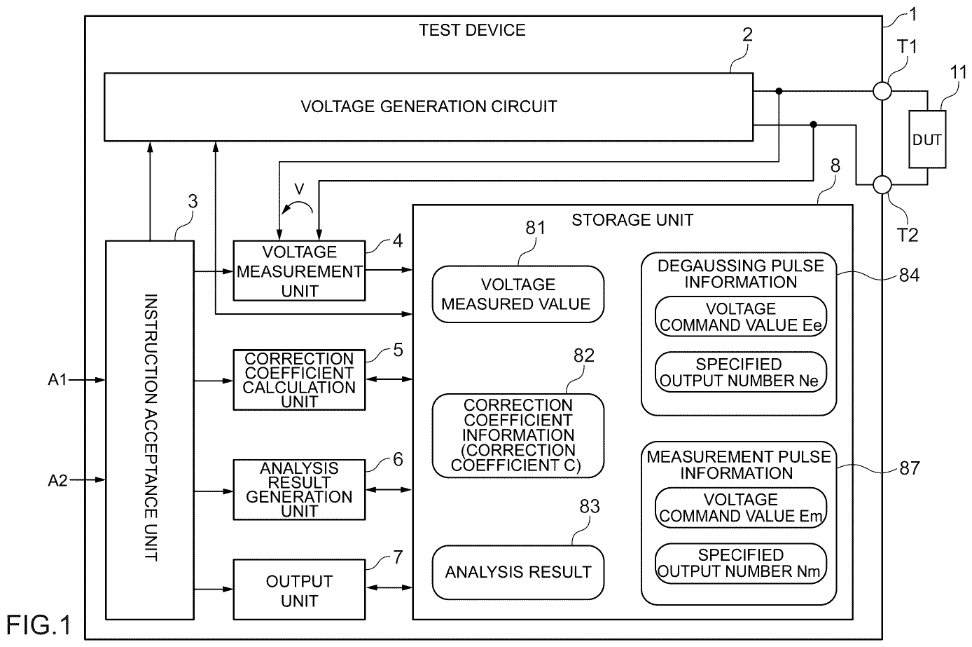

FIG. 1 is a diagram showing a configuration of a test device 1 according to an embodiment.

The test device 1 shown in FIG. 1 is a device that analyzes electric properties of a winding (coil) forming electric equipment such as a rotating machine or a transformer of an electric motor, a power generator, and the like. For example, the test device 1 is an impulse winding test device that on the basis of changes in voltage occurring when a voltage (an impulse voltage) is applied to a winding under test, calculates a value of at least one of an equivalent inductor, an equivalent capacitor, and an equivalent resistor, which is a parameter concerning the winding under test.

The test device 1 has a function of outputting a voltage (hereinafter, also referred to as a “degaussing pulse”) for reducing variation in magnetization of a core in a winding having the core in addition to the function of analyzing electric properties of the winding. The test device 1 further has a function of reducing variation in voltage to be applied to the winding when testing the winding.

The test device 1 has external terminals T1 and T2, a voltage generation circuit 2, an instruction acceptance unit 3, a voltage measurement unit 4, a correction coefficient calculation unit 5, an analysis result generation unit 6, an output unit 7, and a storage unit 8 as functional units for achieving the functions described above as shown in FIG. 1, for example.

The external terminals T1 and T2 are terminals for connecting a winding 11 as a device under test (DUT). For example, one terminal of the winding 11 is connected to the external terminal T1, and another terminal of the winding 11 is connected to the external terminal T2.

The voltage generation circuit 2 is a circuit for applying a desired voltage to the winding 11 under test connected between the external terminals T1 and T2. Hereinafter, an impulse voltage output from the voltage generation circuit 2 during the test of the winding 11 will be referred to as a “measurement pulse”, and an impulse voltage output from the voltage generation circuit 2 for reducing variation in magnetization of the core of the winding 11 under test as described above will be referred to as a “degaussing pulse.”

The voltage generation circuit 2 generates a voltage on the basis of a voltage command value E and a correction coefficient C which will be described later, and outputs the voltage across the external terminal T1 and the external terminal T2. Note that details of a method for generating the voltage to be performed by the voltage generation circuit 2 will be described later.

The instruction acceptance unit 3 is a functional unit that accepts an instruction for the test device 1. The instruction acceptance unit 3 is implemented by, for example, an input interface device that accepts a user operation on the test device 1, such as an operation button or a touch panel, and program processing performed by a CPU.

The instruction acceptance unit 3 may have a communication circuit for performing communication with external equipment, for example, by wire or wirelessly. For example, the instruction acceptance unit 3 may receive, with the communication circuit, a signal transmitted from an information processing device (such as, for example, a PC or tablet terminal) connected to the test device 1 via a wired or wireless network and may instruct another functional unit to execute processing in accordance with the received signal.

The instruction acceptance unit 3 accepts a first instruction A1 and a second instruction A2, for example. The first instruction A1 and the second instruction A2 are input by a user operation on the operation button, the touch panel, or the like described above, the signal received with the communication circuit, or the like.

The first instruction A1 is an instruction to output the degaussing pulse, for example. The first instruction A1 is associated with information (hereinafter, also referred to as “degaussing pulse information”) 84 concerning conditions for outputting the degaussing pulse, for example. The degaussing pulse information 84 includes a voltage command value Ee for specifying a magnitude (amplitude) of the degaussing pulse and a specified output number Ne for specifying the number of times that the degaussing pulse is to be output, for example. Note that the degaussing pulse information 84 may be included in the first instruction A1.

The second instruction A2 is an instruction indicating execution of an analysis related to electric properties of the winding 11 under test, for example. The second instruction A2 is associated with information (hereinafter, also referred to as “measurement pulse information”) 87 concerning the measurement pulse as test conditions. The measurement pulse information 87 includes a voltage command value Em for specifying the magnitude (amplitude) of the measurement pulse and a specified output number Nm for specifying the number of times that the measurement pulse is to be output during the test, for example. The measurement pulse information 87 may be included in the second instruction A2.

In a case of accepting the measurement pulse information 87 (the voltage command value Em and the specified output number Nm), the instruction acceptance unit 3 stores the measurement pulse information 87 in the storage unit 8. In a case of accepting the degaussing pulse information 84 (the voltage command value Ee and the specified output number Ne), the instruction acceptance unit 3 also stores the degaussing pulse information 84 in the storage unit 8.

Note that the measurement pulse information 87 may not be included in the second instruction A2. For example, it is only necessary to set the measurement pulse information 87 in the test device 1 (the storage unit 8) before the measurement pulse is output. A user may input the measurement pulse information 87 to the instruction acceptance unit 3 before the second instruction A2 is input, or the measurement pulse information 87 may be stored in the storage unit 8 in advance. Similarly, it is only necessary to set the degaussing pulse information 84 in the test device 1 before the degaussing pulse is output. The user may input the degaussing pulse information 84 to the instruction acceptance unit 3 before the first instruction A1 is input, or the degaussing pulse information 84 may be stored in the storage unit 8 in advance.

Note that, in addition to the degaussing pulse information 84 and the measurement pulse information 87 described above, the instruction acceptance unit 3 may store, in the storage unit 8, information about a sampling frequency which will be described later and the like, if input as measuring conditions.

The voltage measurement unit 4 is a functional unit that measures a voltage (inter-terminal voltage) V across the external terminal T1 and the external terminal T2. The voltage measurement unit 4 stores a measured value (voltage measured value) 81 of the voltage V in the storage unit 8.

Specifically, the voltage measurement unit 4 samples the voltage V in a predetermined sampling period, thereby acquiring the measured value of the voltage V. The voltage measurement unit 4 is configured to include, for example, a resistance voltage dividing circuit that divides the voltage V across the external terminal T1 and the external terminal T2 and an A/D conversion circuit that converts the voltage divided by the resistance voltage dividing circuit into a digital signal in the predetermined sampling period. The voltage measurement unit 4 acquires time-series data about the measured values (sampling data) of the voltage V by sampling the voltage V in the predetermined sampling period, for example, and stores the time-series data as the voltage measured value 81 in the storage unit 8. Note that the sampling period may be set by a user operation on the instruction acceptance unit 3 or may be set from an external device via the instruction acceptance unit 3, for example.

The correction coefficient calculation unit 5 is a functional unit that calculates the correction coefficient C.

The correction coefficient C is a parameter for correcting the voltage command value such that the voltage output from across the external terminals T1 and T2 has a desired value.

The correction coefficient C is stored in the storage unit 8 as the correction coefficient information 82. For example, an initial value of the correction coefficient (a correction coefficient C0) is stored in advance as the correction coefficient information 82. The correction coefficient calculation unit 5 updates the correction coefficient C in the correction coefficient information 82 each time the correction coefficient C is calculated. Note that the correction coefficient C0 (initial value) may be set by a user operation on the instruction acceptance unit 3 or may be set by external equipment via the instruction acceptance unit 3. In the present embodiment, the correction coefficient C0 shall be stored in the storage unit 8 in advance as an example, and the correction coefficient C0=1.000 shall hold. Note that a method for calculating (updating) the correction coefficient C to be performed by the correction coefficient calculation unit 5 will be described later.

The analysis result generation unit 6 is a functional unit that on the basis of the voltage V measured by the voltage measurement unit 4, generates an analysis result related to electric properties of the winding 11 under test. The analysis result generation unit 6 calculates a value of at least one of an equivalent inductor, an equivalent capacitor, and an equivalent resistor, which is a parameter concerning the winding 11, for example, as an analysis of the electric properties of the winding 11 under test in accordance with a publicly-known analysis technique on the basis of a transient response property of the voltage V across the external terminals T1 and T2 obtained when a voltage (impulse voltage) is applied to the winding 11 connected between the external terminals T1 and T2.

The output unit 7 is a functional unit that outputs information for setting test conditions, information about the analysis result, and the like. The output unit 7 is implemented by a display device such as a liquid crystal display, for example. The display device may display the information for setting the test conditions, the information about the analysis result, and the like on a screen. The display device may also display, on the screen, the transient response property of the voltage measured by the voltage measurement unit 4 as a graph.

Note that, in addition to (or instead of) the above-described display device, for example, the output unit 7 may include a communication circuit that transmits data such as the analysis result to an external information processing device by wire or wirelessly, a circuit that writes data such as the analysis result into a storage device (such as a memory card) connected to the test device 1, and the like.

The storage unit 8 is a functional unit for storing a program and various parameters for the test device 1 to function as an impulse winding test device, the analysis result of the winding 11 under test, and the like. The voltage measured value 81, the correction coefficient information 82, the analysis result 83, the degaussing pulse information 84, the measurement pulse information 87, and the like described above, for example, are stored in the storage unit 8.

The correction coefficient calculation unit 5, the analysis result generation unit 6, and the storage unit 8 described above are implemented by a program processing device, for example. Specifically, in a program processing device (for example, a microcontroller) having a configuration in which a processor such as a CPU, various storage devices such as a RAM and a ROM, and peripheral circuits such as a counter (timer), an A/D conversion circuit, a D/A conversion circuit, a clock generation circuit, and an input/output interface circuit are connected to one another via buses and dedicated lines, the processor executes various types of computation processing in accordance with the program stored in the memory and controls the above-described peripheral circuits on the basis of a result of the processing, whereby the correction coefficient calculation unit 5, the analysis result generation unit 6, and the storage unit 8 are implemented.

Note that some of the functional units forming the test device 1 may be implemented in an external information processing device (such as a PC, a portable terminal such as a tablet terminal, or a server, for example) capable of communicating with the test device 1. For example, the analysis result generation unit 6 may be implemented by the information processing device by the output unit 7 transmitting the voltage measured value 81 and the like to the external information processing device.

Herein, a configuration of the voltage generation circuit 2 will be described.

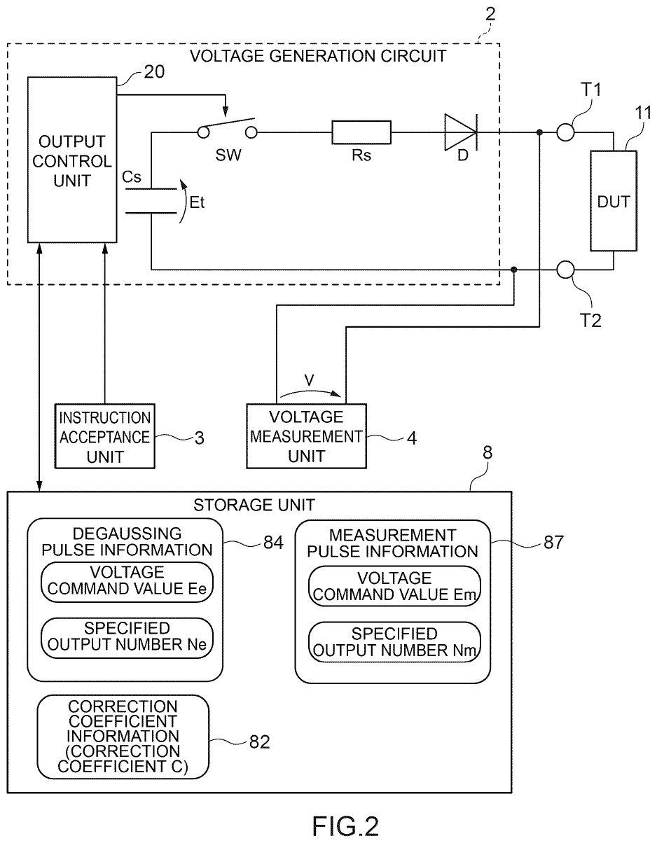

FIG. 2 is a diagram showing an example of the configuration of the voltage generation circuit 2.

As shown in FIG. 2, the voltage generation circuit 2 has a switch SW, an impulse voltage applying capacitor Cs, a current-limiting resistor Rs, a rectifier element D, and an output control unit 20, for example.

The impulse voltage applying capacitor Cs is a capacitor for charging charges for generating an impulse voltage. One end of the impulse voltage applying capacitor Cs is connected to the external terminal T2.

The switch SW is an element for switching between allowance and disallowance of output of the impulse voltage. The switch SW is implemented by a semiconductor element such as a power transistor or a thyristor, for example. The switch SW is connected between another end of the impulse voltage applying capacitor Cs and the external terminal T1.

The current-limiting resistor Rs is an element for limiting a current flowing from the external terminal T1 to the winding 11 under test when the impulse voltage applying capacitor Cs is discharged. The current-limiting resistor Rs is connected between the other end of the impulse voltage applying capacitor Cs and the external terminal T1 in series with the switch SW.

The rectifier element D is an element that passes a current from the impulse voltage applying capacitor Cs side to the external terminal T1 side and interrupts a current from the external terminal T1 side to the impulse voltage applying capacitor Cs side. The rectifier element D is a diode, for example. Note that in the following description, the rectifier element D is also written as the “backflow prevention diode D.”

The backflow prevention diode D is connected between the other end of the impulse voltage applying capacitor Cs and the external terminal T1 in series with the switch SW and the current-limiting resistor Rs. For example, an anode electrode of the backflow prevention diode D is connected to one end of the current-limiting resistor Rs, and a cathode electrode of the backflow prevention diode D is connected to the external terminal T1.

The output control unit 20 is a functional unit that controls charging and discharging of the impulse voltage applying capacitor Cs in accordance with an instruction from the instruction acceptance unit 3. The output control unit 20 is implemented by the program processing device (microcontroller) described above, for example.

The output control unit 20 controls a charging voltage of the impulse voltage applying capacitor Cs and the switch SW on the basis of the degaussing pulse information 84 and the measurement pulse information 87 in accordance with the instruction from the instruction acceptance unit 3, thereby generating the voltage V across the external terminals T1 and T2. For example, the output control unit 20 charges the impulse voltage applying capacitor Cs by a DC power supply (not shown) to obtain a desired voltage in a state in which the switch SW is opened and then closes the switch SW, thereby generating the voltage V across the external terminals T1 and T2.

At this time, there are cases in which the voltage V to be applied to the winding 11 from the external terminals T1 and T2 varies due to variation in properties and the like of the winding 11 which is the device under test, as described above. In other words, the voltage V to be applied to the winding 11 from the external terminals T1 and T2 may be different from “Em” (V≠Em) when the voltage command value is denoted by “Em”, the impulse voltage applying capacitor Cs is charged such that the voltage of the impulse voltage applying capacitor Cs becomes “Em”, and the impulse voltage applying capacitor Cs is discharged by the switch SW. Moreover, there are cases in which the voltage V has a different value per winding 11 under test due to the variation in properties and the like.

Therefore, the output control unit 20 corrects the voltage command value Em using the correction coefficient C calculated such that the voltage V to be applied to the winding 11 from the external terminals T1 and T2 has a desired value, and charges the impulse voltage applying capacitor Cs such that the voltage of the impulse voltage applying capacitor Cs has a value obtained by correcting the voltage command value Em by the correction coefficient C. Then, the output control unit 20 discharges the impulse voltage applying capacitor Cs by the switch SW, thereby applying the voltage V having the desired value to the winding 11.

Next, a method for calculating the correction coefficient C by the test device 1 will be described.

As described above, the correction coefficient C is a parameter for correcting the voltage command value such that the voltage to be output from across the external terminals T1 and T2 has a desired value. The correction coefficient C is calculated and updated by the correction coefficient calculation unit 5.

In a case in which the instruction acceptance unit 3 accepts a predetermined instruction, the voltage generation circuit 2 generates and outputs a voltage (set voltage) Et in accordance with a value obtained by correcting the voltage command value associated with the predetermined instruction by the correction coefficient C. The correction coefficient calculation unit 5 updates the correction coefficient C such that a gap between the voltage V measured by the voltage measurement unit 4 and the voltage command value associated with the predetermined instruction decreases.

Herein, the predetermined instruction is, for example, the first instruction A1 (a command to output the degaussing pulse) or the second instruction A2 (a command to execute an analysis related to the electric properties of the winding 11) described above. In the present embodiment, description will be given assuming that the predetermined instruction is the first instruction A1 as an example.

Specifically, in a case in which the instruction acceptance unit 3 accepts the first instruction, the voltage generation circuit 2 generates a voltage on the basis of the voltage command value associated with the first instruction A1, that is, the voltage command value Ee included in the degaussing pulse information 84, and outputs the voltage. Thereafter, the correction coefficient calculation unit 5 calculates the correction coefficient C such that a gap between the voltage measured by the voltage measurement unit 4 and the voltage command value Ee associated with the first instruction A1 decreases.

At this time, the correction coefficient calculation unit 5 may calculate the correction coefficient C on the basis of a ratio between the voltage V measured by the voltage measurement unit 4 and the voltage command value (Ee) associated with the predetermined instruction. For example, when the correction coefficient before updating is denoted by Cn-1 and the correction coefficient after updating is denoted by Cn, the correction coefficient calculation unit 5 may calculate (update) the correction coefficient Cn on the basis of Equation (1) below.

[Expression 1]

Cₙ=Ee÷V×Cₙ₋₁ (1)

Alternatively, the correction coefficient calculation unit 5 may update the correction coefficient C each time a pulse is output. Specifically, in the case in which the instruction acceptance unit 3 accepts the predetermined instruction, the voltage generation circuit 2 may output a pulse having a voltage in accordance with a value obtained by correcting the voltage command value associated with the predetermined instruction by the correction coefficient a specified number of times, and the correction coefficient calculation unit 5 may update the correction coefficient C each time the pulse is output.

For example, in the case in which the instruction acceptance unit 3 accepts the first instruction A1, the voltage generation circuit 2 outputs a degaussing pulse having a voltage (Et=Ee×C) in accordance with a value obtained by correcting the voltage command value Ee of the degaussing pulse by the correction coefficient C a specified number of times (specified output number) Ne. The correction coefficient calculation unit 5 may update the correction coefficient Cn on the basis of the voltage V measured each time the degaussing pulse is output, the voltage command value Ee, and the immediately preceding correction coefficient Cn-1.

Hereinafter, a procedure of calculating the correction coefficient C will be described.

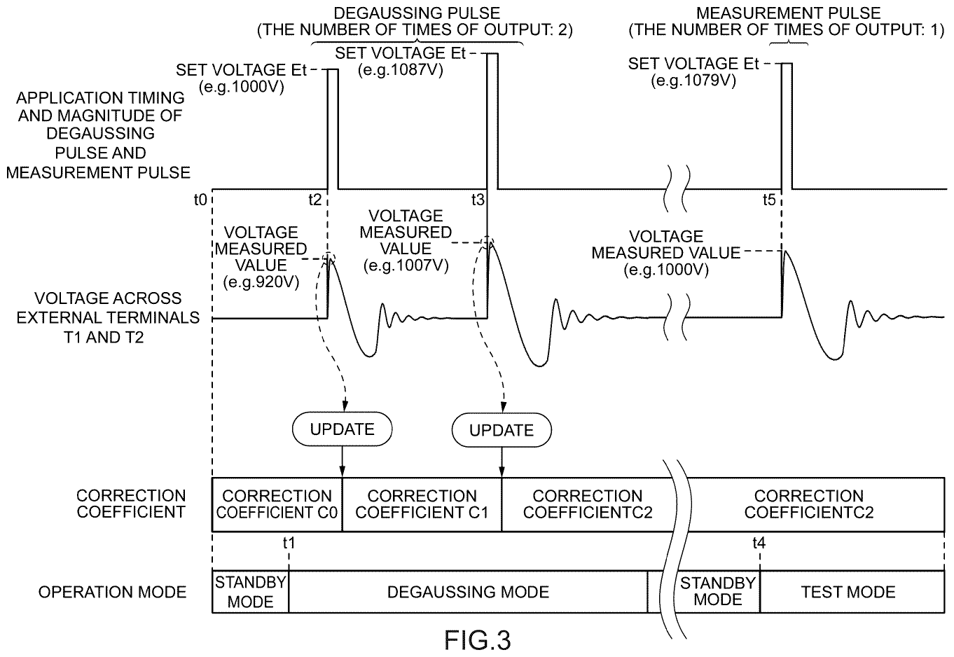

FIG. 3 is a timing chart obtained when the degaussing pulse and the measurement pulse are output from the voltage generation circuit 2.

FIG. 3 shows temporal changes in application timing and magnitude of the degaussing pulse and the measurement pulse output from the voltage generation circuit 2, the voltage across the external terminals T1 and T2, the correction coefficient, the operation mode of the test device 1 sequentially from the upper side in FIG. 3.

The test device 1 has a “standby mode (standby state)” for waiting for input of an instruction to the test device 1, a “degaussing mode”, and a “test mode”, for example, as operation modes. The test device 1, in the degaussing mode, outputs the degaussing pulse to reduce variation in magnetization of the winding 11 under test and calculates (updates) the correction coefficient C, and in the test mode, outputs the measurement pulse to analyze the electric properties of the winding 11 under test.

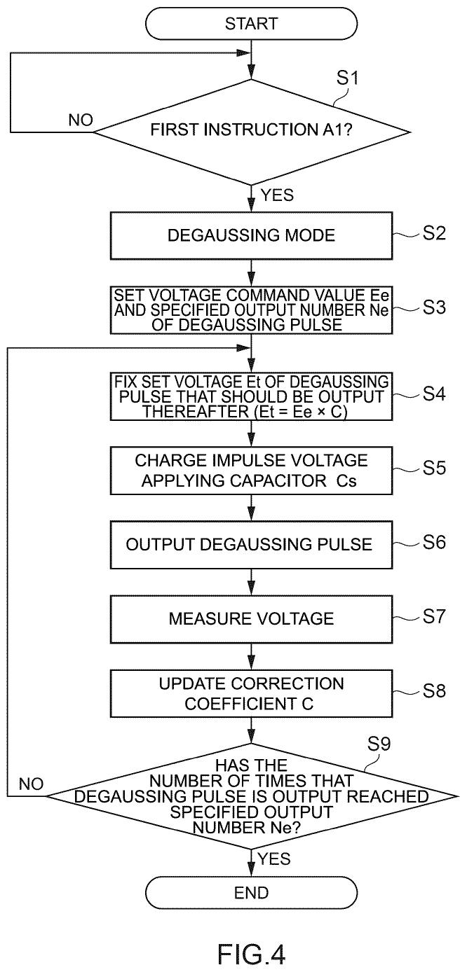

FIG. 4 is a flowchart showing a flow of processing to be performed by the test device 1 in the degaussing mode.

For example, when the test device 1 is powered up at time t0 in FIG. 3, the test device 1 transitions to the “standby mode.” In the standby mode, the test device 1 determines whether the instruction acceptance unit 3 has accepted the first instruction A1 (step S1). In a case in which the instruction acceptance unit 3 has not accepted the first instruction A1 (step S1: NO), the test device 1 maintains the standby mode.

For example, in the case in which the instruction acceptance unit 3 has accepted the first instruction A1 at time t1 in FIG. 3 (step S1: YES), the test device 1 transitions to the degaussing mode (step S2).

In the degaussing mode, the test device 1 sets conditions for the degaussing pulse (step S3). Specifically, the output control unit 20 of the voltage generation circuit 2 reads out the voltage command value Ee and the specified output number Ne of the degaussing pulse as the degaussing pulse information 84 as well as the correction coefficient C included in the correction coefficient information 82 stored in the storage unit 8. Herein, it is assumed that the voltage command value Ee=1000 V, the specified output number Ne=2, and the correction coefficient C=C0 (initial value)=1.000 hold.

Thereafter, the output control unit 20 fixes a set voltage Et of the degaussing pulse that should be output thereafter on the basis of the voltage command value Ee and the correction coefficient C (step S4). For example, the output control unit 20 fixes a value (=Ee×C0=1000 V) obtained by multiplying the voltage command value Ee by the correction coefficient C0 as the set voltage Et of the degaussing pulse.

Thereafter, the output control unit 20 charges the impulse voltage applying capacitor Cs by the DC power supply not shown such that the voltage of the impulse voltage applying capacitor Cs becomes the set voltage Et (=1000 V) (step S5).

Thereafter, the test device 1 outputs a first degaussing pulse (step S6). Specifically, the output control unit 20 turns on the switch SW at time t2 in FIG. 3. The charges charged in the impulse voltage applying capacitor Cs are thereby discharged through the current-limiting resistor Rs and the backflow prevention diode D, and the degaussing pulse of the voltage (amplitude) V is produced across the external terminals T1 and T2. When the degaussing pulse is output in step S6, the voltage measurement unit 4 starts measurement of the voltage V across the external terminals T1 and T2 (step S7).

Thereafter, the correction coefficient calculation unit 5 calculates the correction coefficient C (step 8). Specifically, as shown in FIG. 3, the correction coefficient calculation unit 5 acquires a maximum value of the voltage V across the external terminals T1 and T2 measured by the voltage measurement unit 4, and calculates a new correction coefficient C on the basis of the set voltage Et fixed in step S4, the maximum value Vmax of the voltage V measured in step S7, and the immediately preceding correction coefficient C. For example, in a case in which Vmax=920 V holds, in which the immediately preceding correction coefficient is C0 (initial value), and in which the correction coefficient after correction is C1, the correction coefficient calculation unit 5 calculates the correction coefficient C1 on the basis of Equation (2) below and stores the correction coefficient C1 as the correction coefficient information 82 in the storage unit 8. The correction coefficient information 82 in the storage unit 8 is thereby updated.

[Expression 2]

C₁=Ee÷Vmax×C₀=1000÷920×1.000=1.087 (2)

Thereafter, the test device 1 determines whether the number of times that the degaussing pulse is output has reached the specified output number Ne (step S9). In a case in which the number of times that the degaussing pulse is output has not reached the specified output number Ne (step S9: NO), the test device 1 executes steps S4 to S9 again.

In the case of the example described above, the degaussing pulse has been output only once whereas the specified output number Ne=2. Thus, the test device 1 returns to step S4, and the output control unit 20 first fixes the set voltage Et of the degaussing pulse that should be output thereafter (step S4). For example, the output control unit 20 fixes a value (=Ee×C=1000×1.087=1087 V) obtained by multiplying the voltage command value Ee by the updated correction coefficient C1 as the set voltage Et of the degaussing pulse that should be output at a second time.

Thereafter, the output control unit 20 charges the impulse voltage applying capacitor Cs by the DC power supply not shown such that the voltage of the impulse voltage applying capacitor Cs becomes the set voltage Et (=1087 V) (step S5).

Thereafter, the test device 1 outputs a second degaussing pulse (=1087 V) (step S6). Specifically, the output control unit 20 turns on the switch SW at time t3 in FIG. 3. The charges charged in the impulse voltage applying capacitor Cs are thereby discharged through the current-limiting resistor Rs and the backflow prevention diode D, and the degaussing pulse of the voltage (amplitude) V is produced across the external terminals T1 and T2. When the second degaussing pulse is output in step S6, the voltage measurement unit 4 starts measurement of the voltage V across the external terminals T1 and T2 (step S7).

Thereafter, the correction coefficient calculation unit 5 calculates (updates) the correction coefficient (step 8). Specifically, as shown in FIG. 3, the correction coefficient calculation unit 5 acquires the maximum value of the voltage V across the external terminals T1 and T2 measured by the voltage measurement unit 4 and updates the correction coefficient C on the basis of the set voltage Et fixed in step S4, the maximum value Vmax of the voltage V measured in step S7, and the immediately preceding correction coefficient C. For example, in a case in which the maximum value Vmax of the voltage V measured after the time t3 is 1007 V, in which the immediately preceding correction coefficient is C1 (=1.087), and in which the correction coefficient after correction is C2, the correction coefficient calculation unit 5 calculates the correction coefficient C2 on the basis of Equation (3) below and stores the correction coefficient C2 as the correction coefficient information 82 in the storage unit 8. The correction coefficient information in the storage unit 8 is thereby updated.

[Expression 3]

C₂=Ee÷Vmax×C₁=1000÷1007×1.087=1.079 (3)

Thereafter, the test device 1 determines whether the number of times that the degaussing pulse is output has reached the specified output number Ne (step S9). In the case of the example described above, the number of times (=2) that the degaussing pulse is output has reached the specified output number Ne (=2) (step S9: YES). Thus, the test device 1 terminates the processing of updating the correction coefficient C (step S10). Then, the test device 1 switches from the degaussing mode to the standby mode, for example.

The correction coefficient C for applying a desired voltage to the winding 11 under test can be calculated by the above processing. Note that although the case in which the specified output number Ne of the degaussing pulse (the number of times that the correction coefficient is updated) is “2” has been illustrated in the example described above, the present invention is not limited to this. It is only necessary that the specified output number Ne should be more than or equal to 1.

Next, processing to be performed by the test device 1 in the test mode will be described.

In a case in which the analysis related to the electric properties of the winding 11 under test is executed, the voltage generation circuit 2 generates and outputs a voltage in accordance with a value obtained by correcting the voltage command value associated with the analysis related to the electric properties of the winding 11 under test by the correction coefficient C, and the analysis result generation unit 6 generates an analysis result 83 on the basis of the voltage measured by the voltage measurement unit 4.

Herein, the voltage command value associated with the analysis related to the electric properties of the winding 11 under test is the voltage command value Em of the measurement pulse information 87, for example.

For example, in a case in which the instruction acceptance unit 3 accepts the second instruction A2 to instruct execution of the analysis related to the electric properties of the winding 11 under test after calculation of the correction coefficient, the voltage generation circuit 2 generates and outputs the voltage in accordance with a value obtained by correcting the voltage command value Em associated with the second instruction A2 by the correction coefficient C, and the analysis result generation unit 6 generates the analysis result 83 on the basis of the voltage measured by the voltage measurement unit 4.

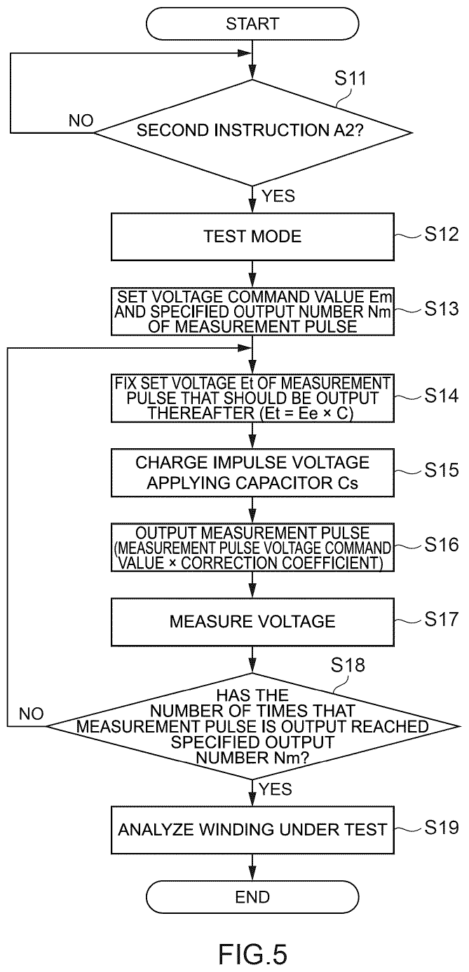

FIG. 5 is a flowchart showing a flow of processing to be performed by the test device 1 in the test mode.

In the following description, it is assumed that the processing of updating the correction coefficient C described above (FIG. 4) is executed before executing the processing in the test mode and that the correction coefficient C2 (=1.079) has been stored as the correction coefficient information 82 in the storage unit 8.

For example, the test device 1 determines whether the instruction acceptance unit 3 has accepted the second instruction A2 in the standby mode (step S11). In a case in which the instruction acceptance unit 3 has not accepted the second instruction A2 (step S11: NO), the test device 1 maintains the standby mode.

For example, in a case in which the instruction acceptance unit 3 accepts the second instruction A2 at time t4 in FIG. 3 (step S11: YES), the test device 1 transitions to the test mode (step S12).

In the test mode, the test device 1 sets conditions for the measurement pulse (step S3). Specifically, the output control unit 20 reads out the voltage command value Em and the specified output number Nm as the measurement pulse information 87 as well as the correction coefficient C2 included in the correction coefficient information 82 stored in the storage unit 8. Herein, it is assumed that the voltage command value Em=1000 V, the specified output number Ne=1, and the correction coefficient C2=1.079 hold.

Thereafter, the output control unit 20 fixes the set voltage Et of the measurement pulse that should be output thereafter on the basis of the voltage command value Em and the correction coefficient C2 (step S14). For example, the output control unit 20 fixes a value (=Em×C2=1079 V) obtained by multiplying the voltage command value Em by the correction coefficient C2 as the set voltage Et that should be set in the impulse voltage applying capacitor Cs.

Thereafter, the output control unit 20 charges the impulse voltage applying capacitor Cs by the DC power supply not shown such that the voltage of the impulse voltage applying capacitor Cs becomes the set voltage Et (=1079 V) (step S15).

Thereafter, the test device 1 outputs the measurement pulse (=1079 V) (step S16). Specifically, the output control unit 20 turns on the switch SW at time t5 in FIG. 3. The charges charged in the impulse voltage applying capacitor Cs are thereby discharged through the current-limiting resistor Rs and the backflow prevention diode D, and the measurement pulse of the voltage (amplitude) V is produced across the external terminals T1 and T2. When the measurement pulse is output in step S16, the voltage measurement unit 4 starts measurement of the voltage V across the external terminals T1 and T2 and stores a measurement result of the voltage V as the voltage measured value 81 in the storage unit 8 (step S17). At this time, the maximum value of the voltage V is about 1000 V because the set voltage Et of the impulse voltage applying capacitor Cs has been adjusted by the correction coefficient C2 (Et=1079 V).

Thereafter, the test device 1 determines whether the number of times that the measurement pulse is output has reached the specified output number Nm (step S18). In a case in which the number of times that the measurement pulse is output has not reached the specified output number Nm (step S18: NO), the test device 1 executes steps S14 to S18 again.

In the case of the example described above, the number of times (=1) that the measurement pulse is output has reached the specified output number Nm (=1) (step S18: YES). Thus, the test device 1 executes processing of analyzing the electric properties of the winding 11 under test (step S19). Specifically, the analysis result generation unit 6 calculates various parameters of the winding 11 by the technique described above using the voltage measured value 81 measured in step S17 and stores the various parameters as the analysis result 83 in the storage unit 8, and the output unit 7 displays information related to the analysis result 83 about the winding 11 on the screen of the display device, for example. Then, the test device 1 switches from the test mode to the standby mode, for example.

As described above, in the case in which the instruction acceptance unit 3 accepts a predetermined instruction (for example, the first instruction A1) in the test device 1 according to the embodiment, the voltage generation circuit 2 generates and outputs the voltage (the set voltage Et=Ee×C) in accordance with the value obtained by correcting the voltage command value (for example, the voltage command value Ee) associated with the predetermined instruction by the correction coefficient C, and the correction coefficient calculation unit 5 updates the correction coefficient C such that the gap between the voltage V measured by the voltage measurement unit 4 and the voltage command value (Ee) associated with the predetermined instruction decreases. In addition, when the analysis related to the electric properties of the winding 11 is executed, the voltage generation circuit 2 generates and outputs the voltage (the set voltage Et=Em×C) in accordance with the value obtained by correcting the voltage command value (for example, the voltage command value Em) associated with the analysis related to the electric properties of the winding 11 by the correction coefficient C, and the analysis result generation unit 6 generates the analysis result 83 on the basis of the voltage V measured by the voltage measurement unit 4 at that time.

With this configuration, the correction coefficient C is adjusted such that the voltage to be applied to the winding 11 under test has a desired magnitude, and the voltage of the measurement pulse to be applied to the winding 11 under test can be fixed on the basis of the adjusted correction coefficient C. This enables variation in the voltage to be applied to the winding 11 under test resulting from the properties of the winding 11 under test and the like to be reduced.

In addition, in the case in which the instruction acceptance unit 3 accepts the predetermined instruction in the test device 1, the voltage generation circuit 2 may output the pulse having the voltage in accordance with the value obtained by correcting the voltage command value associated with the predetermined instruction by the correction coefficient a specified number of times, and the correction coefficient calculation unit 5 may update the correction coefficient each time the pulse is output.

With this configuration, the number of times that the correction coefficient C is updated increases as the number of times that the pulse (for example, the degaussing pulse) to be applied to the winding 11 under test is output before the test is performed is increased. Thus, the accuracy of the correction coefficient C can be improved, and variation in voltage to be applied to the winding 11 under test can be reduced further. In addition, it is only necessary to specify the number of times that the degaussing pulse is output in accordance with the accuracy required for the voltage to be applied to the winding 11 under test. Thus, the test device 1 which is adaptable to various needs of a user and which is convenient can be implemented.

In addition, the predetermined instruction may be the first instruction A1 which is the instruction to output the degaussing pulse. With this configuration, it is not necessary to newly provide an operation button or the like and a command or the like for updating the correction coefficient C. In addition, reduction in variation in magnetization state of the winding 11 and updating of the correction coefficient C are performed merely by operating the test device 1 to instruct output of the degaussing pulse. This enables an increase in analysis time caused by performing updating of the correction coefficient C to be reduced.

In addition, in the case in which the instruction acceptance unit 3 accepts the second instruction A2 which is the instruction to execute the analysis related to the electric properties of the winding 11 under test in the test device 1, the voltage generation circuit 2 may generate and output the voltage in accordance with the value obtained by correcting the voltage command value Em associated with the second instruction A2 by the correction coefficient C, and the analysis result generation unit 6 may generate the analysis result 83 on the basis of the voltage measured by the voltage measurement unit 4.

With this configuration, the processing of calculating the correction coefficient and the processing of analyzing the winding are executed respectively in accordance with the first instruction A1 and the second instruction A2 which are independent from each other. This allows the user to cause the test device 1 to execute the updating of the correction coefficient and the analysis of the winding in distinction from each other at desired timings.

In addition, in the test device 1, the correction coefficient calculation unit 5 may update the correction coefficient C on the basis of the ratio between the voltage V measured by the voltage measurement unit 4 and the voltage command value (Ee) associated with the predetermined instruction. For example, the correction coefficient calculation unit 5 may update the correction coefficient Cn on the basis of Equation (1) above.

With this configuration, the correction coefficient can be updated by a simpler calculation, which enables an increase in computational burden by the test device 1 (the program processing device) caused by incorporating the voltage correcting function into the test device 1 to be reduced.

In addition, in the test device 1, it is preferable that the voltage command value associated with the predetermined instruction A1 should correspond to the voltage command value associated with the analysis related to the electric properties of the winding 11 under test. For example, it is preferable to cause the voltage command value Ee of the degaussing pulse to correspond to the voltage command value Em of the measurement pulse (Ee=Em). With this configuration, the correction coefficient is adjusted in conformity to the voltage that should be applied to the winding 11 during the analysis. Thus, the accuracy of the voltage of the measurement pulse can be improved further.

### Expansion of Embodiment

Although the invention made by the inventor of the present application has been described above specifically on the basis of the embodiment, it is needless to say that the present invention is not limited to that embodiment and may be modified variously within a range not departing from the spirit of the invention.

For example, the case in which the predetermined instruction to serve as a trigger to start the processing of calculating the correction coefficient is the first instruction A1 (the instruction to output the degaussing pulse) has been illustrated in the above-described embodiment, but the present invention is not limited to this. For example, the predetermined instruction may be an instruction (for example, the instruction to calculate the correction coefficient) different from the instruction to output the degaussing pulse. In this case, it is only necessary to newly provide the test device 1 with a user interface such as an operation button and a command for the above-described instruction.

In addition, the case in which the predetermined instruction to serve as the trigger to start the processing of calculating the correction coefficient is the first instruction A1, that is, the case in which the test device 1 executes calculation (updating) of the correction coefficient when the first instruction A1 is input to the test device 1 has been illustrated in the above-described embodiment, but the present invention is not limited to this. For example, in the case in which the second instruction A2 is input to the test device 1, the test device 1 may consecutively execute the processing of calculating the correction coefficient C and the processing of analyzing the winding 11 in accordance with input of the second instruction A2.

Specifically, the predetermined instruction is the second instruction A2 (the instruction to execute the analysis related to the electric properties of the winding 11 under test). More specifically, in the case in which the instruction acceptance unit 3 accepts the second instruction A2, the voltage generation circuit 2 generates and outputs a voltage based on the voltage command value Em associated with the second instruction A2, and the correction coefficient calculation unit 5 calculates the correction coefficient C such that the gap between the voltage measured by the voltage measurement unit 4 and the voltage command value Em associated with the second instruction A2 decreases. Then, after calculation of the correction coefficient C, the voltage generation circuit 2 generates and outputs the voltage in accordance with the value obtained by correcting the voltage command value Em by the correction coefficient C, and the analysis result generation unit 6 generates the analysis result 83 on the basis of the voltage measured by the voltage measurement unit 4.

With this configuration, the calculation of the correction coefficient C and the analysis related to the electric properties of the winding 11 through use of the correction coefficient C are performed consecutively merely by a user input of the instruction (the second instruction A2) to execute the analysis related to the electric properties of the winding 11. Thus, it is not necessary for the user to input the instruction (the first instruction A1) to output the degaussing pulse beforehand.

In this case, the voltage generation circuit 2 may use the measurement pulse information 87 as the degaussing pulse information 84. For example, the voltage generation circuit 2 may set the voltage command value Ee of the degaussing pulse at the same value as the voltage command value Em of the measurement pulse information 87 and output the degaussing pulse. The voltage generation circuit 2 may also set the specified output number Ne of the degaussing pulse at the same value as the specified output number Nm of the measurement pulse and output the degaussing pulse. Alternatively, the degaussing pulse information 84 may be set in the storage unit 8 in advance. With this configuration, it is sufficient for the user only to set the measurement pulse information 87, and it is not necessary to set the degaussing pulse information 84.

In addition, the case in which updating of the correction coefficient C is performed each time the degaussing pulse is output in the case in which the test device 1 outputs a plurality of degaussing pulses has been illustrated in the above-described embodiment, but the present invention is not limited to this. In other words, it is only necessary for the correction coefficient calculation unit 5 to calculate the correction coefficient C by the technique described above on the basis of the measured value of the voltage V obtained when at least one degaussing pulse of the plurality of degaussing pulses is applied to the winding 11.

For example, the correction coefficient calculation unit 5 may calculate the correction coefficient Cn on the basis of the measured value of the voltage V obtained when an initially output degaussing pulse is applied to the winding 11 and the correction coefficient Cn-1, or may calculate the correction coefficient Cn on the basis of the measured value of the voltage V obtained when a finally output degaussing pulse is applied to the winding 11 and the correction coefficient Cn-1. Alternatively, in the case in which the degaussing pulse is output Ne times, the correction coefficient calculation unit 5 may calculate the correction coefficient C on the basis of each of degaussing pulses initially output n (<Ne) times, or may calculate the correction coefficient C on the basis of each of degaussing pulses finally output n times. In other words, the number of times (the specified output number Ne) that the degaussing pulse is output and the number of times that the correction coefficient is updated may not correspond to each other.

In addition, the case in which the voltage command value Ee of the first degaussing pulse is set at 1000 V in order to make the voltage to be applied to the winding 11 during the test 1000 V has been illustrated in the above-described embodiment as an example, but the present invention is not limited to this. For example, a voltage command value necessary for applying 1000 V to the winding 11 which is a good product may be measured in advance, and the voltage command value may be used as the voltage command value of the first degaussing pulse. For example, in a case in which the voltage command value for applying 1000 V to the winding 11 is 1090 V, the voltage command value Ee of the first degaussing pulse may be set at “1090 V.” Alternatively, the first degaussing pulse may be output with the initial value C0 of the correction coefficient set at “1.090 (=1090 V/1000 V).”

In addition, the case in which the degaussing pulse is used as the pulse to be applied to the winding 11 for calculation of the correction coefficient has been illustrated in the above-described embodiment, but the type of pulse is not limited to this. For example, a pulse which is the same as the measurement pulse to be applied during the analysis related to the electric properties of the winding 11 under test may be applied to the winding 11 for calculation of the correction coefficient. At this time, the number of times that the pulse is output for calculation of the correction coefficient may be the same as or may be different from the number of times (the specified output number Nm) that the measurement pulse is output.

In addition, in a case in which the correction coefficient C calculated by updating exceeds a predetermined range, the correction coefficient calculation unit 5 may restrict the correction coefficient C to an upper limit value or a lower limit value of the predetermined range, or the voltage generation circuit 2 may stop output of the degaussing pulse or the measurement pulse after the output unit 7 outputs information indicating an abnormal state (error). With this configuration, in a case in which an abnormality (a short failure, an open failure, or the like) occurs in the winding under test itself, the correction coefficient C can be prevented from being set at an abnormal value so that an inappropriate voltage is output from the external terminals T1 and T2.

In addition, the flowcharts described above indicate one example for describing operation, and the present invention is not limited to this. In other words, steps shown in each of the flowcharts indicate a specific example and are not limited to this flow. For example, some steps may be changed in order, another step may be inserted between respective steps, or some steps may be performed in parallel.

### LIST OF REFERENCE SIGNS

1 test device,
2 voltage generation circuit,
3 instruction acceptance unit,
4 voltage measurement unit,
5 correction coefficient calculation unit,
6 analysis result generation unit,
7 output unit,
8 storage unit,
81 voltage measured value,
82 correction coefficient information,
83 analysis result,
84 degaussing pulse information,
87 measurement pulse information,
A1 first instruction,
A2 second instruction,
Cs impulse voltage applying capacitor,
Rs current-limiting resistor,
D rectifier element (backflow prevention diode),
T1 external terminal (first external terminal),
T2 external terminal (second external terminal)

1. A test device comprising:
a first external terminal to which one terminal of a winding under test is to be connected;
a second external terminal to which another terminal of the winding under test is to be connected;
an instruction acceptance unit that accepts an instruction;
a correction coefficient calculation unit that calculates a correction coefficient;
a voltage generation circuit that generates a voltage on a basis of a voltage command value and the correction coefficient and outputs the voltage across the first external terminal and the second external terminal;
a voltage measurement unit that performs measurement of a voltage across the first external terminal and the second external terminal; and
an analysis result generation unit that performs an analysis related to an electric property of the winding under test on a basis of the voltage measured by the voltage measurement unit and generates an analysis result, wherein
in a case in which the instruction acceptance unit accepts a predetermined instruction including an instruction to output a degaussing pulse which is a voltage for reducing variation in magnetization of a core in the winding having the core, the voltage generation circuit generates a voltage on a basis of the voltage command value associated with the predetermined instruction and outputs the voltage, and the correction coefficient calculation unit calculates the correction coefficient such that a gap between the voltage measured by the voltage measurement unit and the voltage command value associated with the predetermined instruction decreases, and
in a case in which the analysis is executed, the voltage generation circuit generates and outputs a voltage in accordance with a value obtained by correcting the voltage command value associated with the analysis by the correction coefficient, and the analysis result generation unit generates the analysis result on a basis of the voltage measured by the voltage measurement unit.

2. The test device according to claim 1, wherein in the case in which the instruction acceptance unit accepts the predetermined instruction, the voltage generation circuit outputs a pulse having a voltage in accordance with a value obtained by correcting the voltage command value associated with the predetermined instruction by the correction coefficient a specified number of times, and the correction coefficient calculation unit updates the correction coefficient each time the pulse is output.

3. The test device according to claim 1, wherein the correction coefficient calculation unit calculates the correction coefficient on a basis of a ratio between the voltage measured by the voltage measurement unit and the voltage command value associated with the predetermined instruction.

4. The test device according to claim 1, wherein
in a case in which the instruction acceptance unit accepts an instruction to execute the analysis after calculation of the correction coefficient, the voltage generation circuit generates and outputs a voltage in accordance with a value obtained by correcting the voltage command value associated with the analysis by the correction coefficient, and the analysis result generation unit generates the analysis result on the basis of the voltage measured by the voltage measurement unit.

5. The test device according to claim 1, wherein
the predetermined instruction includes an instruction to execute the analysis, and
after calculation of the correction coefficient, the voltage generation circuit generates and outputs a voltage in accordance with a value obtained by correcting the voltage command value associated with the measurement by the correction coefficient, and the analysis result generation unit generates the analysis result on the basis of the voltage measured by the voltage measurement unit.

6. The test device according to claim 1, wherein the voltage command value associated with the predetermined instruction corresponds to the voltage command value associated with the measurement.

7. A test method to be performed using a test device including a first external terminal to which one terminal of a winding under test is to be connected, a second external terminal to which another terminal of the winding under test is to be connected, an instruction acceptance unit that accepts an instruction, a correction coefficient calculation unit that calculates a correction coefficient, a voltage generation circuit that generates a voltage on a basis of a voltage command value having been set and the correction coefficient and outputs the voltage across the first external terminal and the second external terminal, a voltage measurement unit that measures a voltage across the first external terminal and the second external terminal, and an analysis result generation unit that performs an analysis related to an electric property of the winding under test on a basis of the voltage measured by the voltage measurement unit and generates an analysis result, the test method comprising:
a first step in which the instruction acceptance unit accepts a predetermined instruction including an instruction to output a degaussing pulse which is a voltage for reducing variation in magnetization of a core in the winding having the core;
a second step in which, after the first step, the voltage generation circuit generates and outputs a voltage in accordance with a value obtained by correcting the voltage command value associated with the predetermined instruction by the correction coefficient;
a third step in which the voltage measurement unit measures a voltage across the first external terminal and the second external terminal obtained when the voltage generation circuit outputs the voltage in the second step;
a fourth step in which the correction coefficient calculation unit calculates the correction coefficient such that a gap between the voltage measured in the third step and the voltage command value associated with the predetermined instruction decreases;
a fifth step in which in a case in which the analysis is executed, the voltage generation circuit generates and outputs a voltage in accordance with a value obtained by correcting the voltage command value associated with the analysis by the correction coefficient;
a sixth step in which the voltage measurement unit measures a voltage across the first external terminal and the second external terminal obtained when the voltage generation circuit outputs the voltage in the fifth step; and
a seventh step in which the analysis result generation unit generates the analysis result on a basis of the voltage measured in the sixth step.
